(19) United States
(12) Patent Application Publication
(10) Pub. No.: US 2010/0224894 A1
(43) Pub. Date: Sep. 9, 2010

(54) III-NITRIDE SEMICONDUCTOR LIGHT EMITTING DEVICE AND METHOD FOR FABRICATING THE SAME

(75) Inventors: Keuk KIM, Gyeonggi-do (KR); Yu-hang CHOI, Gyeonggi-do (KR); Chae-seok LIM, Gyeonggi-do (KR); Chi-kwon PARK, Gyeonggi-do (KR)

Correspondence Address: HUSCH BLACKWELL SANDERS LLP, 190 Carondelet Plaza, Suite 600, ST. LOUIS, MO, 63105, US

(73) Assignee: WOOREE LST CO., LTD, Gyeonggi-do (KR)

(21) Appl. No.: 12/650,229

(22) Filed: Dec. 30, 2009

(30) Foreign Application Priority Data
Mar. 5, 2009 (KR) 10-2009-0018871
Aug. 18, 2009 (KR) 10-2009-0076071

(51) Int. Cl. H01L 33/00; H01L 21/302

(52) U.S. Cl. 257/98; 438/29; 257/E33.074; 257/E21.214

(57) ABSTRACT

The present disclosure relates to a III-nitride semiconductor light emitting device, including: a substrate; a plurality of III-nitride semiconductor layers grown over the substrate and including an active layer generating light by recombination of electrons and holes; a scattering surface provided on the substrate to scatter the light generated in the active layer; and a sub-scattering portion ruggedly formed on the scattering surface.

### CROSS-REFERENCE TO RELATED APPLICATION

This application claims the benefit of Korean Patent Application Nos. 10-2009-0018871 filed on Mar. 6, 2009 and 10-2009-0076071 filed on Aug. 18, 2009, both of which are hereby incorporated by reference as if fully set forth herein.

### BACKGROUND OF THE INVENTION

The present disclosure relates generally to a III-nitride semiconductor light emitting device and a method for fabricating the same, and more particularly, to a III-nitride semiconductor light emitting device and a method for fabricating the same which can improve the external quantum efficiency and reduce crystal defects during the growth of a III-nitride semiconductor.

FIG. 1 illustrates an example of conventional III-nitride semiconductor light emitting device. The III-nitride semiconductor light emitting device includes a substrate 100, a buffer layer 200 grown on the substrate 100, an n-type nitride semiconductor layer 300 grown on the buffer layer 200, an active layer 400 grown on the n-type nitride semiconductor layer 300, a p-type nitride semiconductor layer 500 grown on the active layer 400, a p-side electrode 600 formed on the p-type nitride semiconductor layer 500, a p-side bonding pad 700 formed on the p-side electrode 600, an n-side electrode 800 formed on the n-type nitride semiconductor layer 300 exposed by mesa-etching the p-type nitride semiconductor layer 500 and the active layer 400, and a protection film 900.

FIG. 2 illustrates an example of a light emitting device disclosed in International Publication Nos. WO 02/75821 and WO 03/10831. Patterns are formed on a substrate 40. These patterns effectively scatter light to improve the external quantum efficiency and reduce crystal defects during the growth of a III-nitride semiconductor layer 41.

Here, the III-nitride semiconductor layers 41 start to be grown on the substrate 40 between the patterns and on top surfaces of the patterns, and then are brought into contact with each other. After the growth is facilitated in the contact regions, the III-nitride semiconductor layer 40 has a flat surface.

FIG. 3 illustrates an example of a light emitting device disclosed in International Publication No. WO 03/10831 and U.S. Patent Publication No. 2005-082546. As semispherical convex portions 51 are formed on a substrate 50, a III-nitride semiconductor layer 52 is prevented from being grown on the convex portions 51. The III-nitride semiconductor layer 52 is planarized faster than that of FIG. 2.

FIG. 4 illustrates a photograph of the III-nitride semiconductor grown on the conventional substrate with the convex portions thereon. While it is known that the III-nitride semiconductor is seldom grown on the side surfaces of the patterned substrate 40 of FIG. 2 and the surfaces of the convex portions 51 of FIG. 3, the III-nitride semiconductor is grown on some parts (see D in FIG. 4). The grown III-nitride semiconductor may become a defect in the final light emitting device.

There is thus a need for an improved III-nitride semiconductor light emitting device and fabricating method thereof to resolve the aforementioned issues. The present invention provides an advance in the art by providing III-nitride semiconductor light emitting device and fabricating method thereof.

Further objectives and advantages of the present invention will become apparent from a careful reading of a detailed description provided herein below, with appropriate reference to the accompanying drawings.

### SUMMARY OF THE INVENTION

This section provides a general summary of the disclosure and is not a comprehensive disclosure of its full scope or all of its features.

According to one aspect of the present disclosure, there is provided a III-nitride semiconductor light emitting device, including: a substrate; a plurality of III-nitride semiconductor layers grown over the substrate and including an active layer generating light by recombination of electrons and holes; a scattering surface provided on the substrate to scatter the light generated in the active layer; and a sub-scattering portion ruggedly formed on the scattering surface.

According to another aspect of the present disclosure, there is provided a method for fabricating a III-nitride semiconductor light emitting device, the method including: a mask formation step of forming a first mask for forming a scattering surface on a substrate and a second mask for forming a sub-scattering portion on the scattering surface; and an etching step of forming the scattering surface and the sub-scattering portion by dry etching.

The advantageous effects of the present disclosure will be described in the latter part of the best mode for carrying out the invention.

### BRIEF DESCRIPTION OF THE DRAWINGS

FIG. 1 is a view of an example of a conventional III-nitride semiconductor light emitting device.

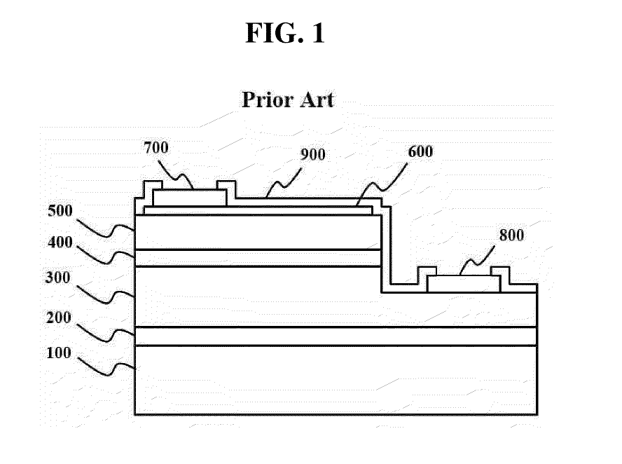

FIG. 2 is a view of an example of a light emitting device disclosed in International Publication Nos. WO 02/75821 and WO 03/10831.

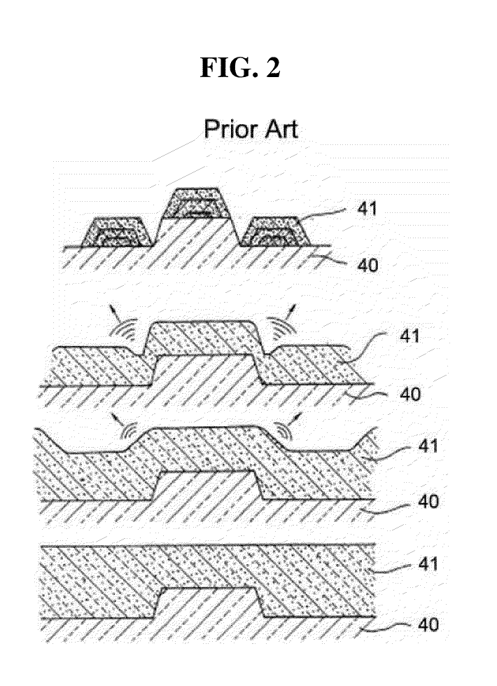

FIG. 3 is a view of an example of a light emitting device disclosed in International Publication No. WO 03/10831 and U.S. Patent Publication No. 2005-082546.

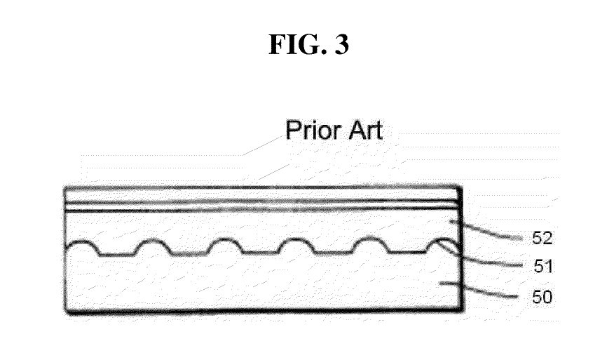

FIG. 4 is a photograph of a III-nitride semiconductor grown on a conventional substrate with convex portions thereon.

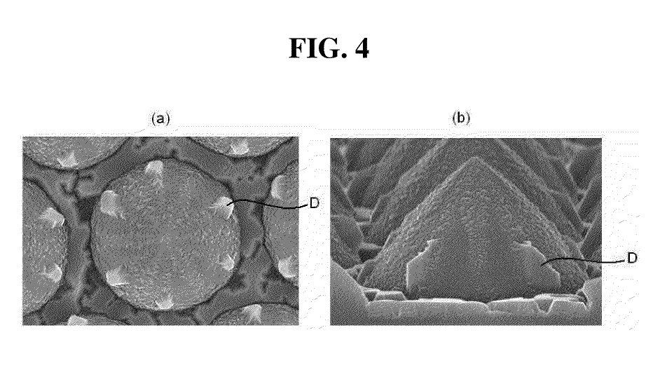

FIG. 5 is a view of an embodiment of a III-nitride semiconductor light emitting device according to the present disclosure.

FIG. 6 is a photograph of an example of a substrate with a scattering surface and a sub-scattering portion thereon according to the present disclosure.

FIG. 7 is a view of some examples of the scattering surface according to the present disclosure.

FIG. 8 is a view of the other examples of the scattering surface according to the present disclosure.

FIG. 9 is an explanatory view of an embodiment of a method for fabricating a III-nitride semiconductor light emitting device according to the present disclosure.

FIG. 10 is an explanatory view of another example of a method for forming a mask according to the present disclosure.

FIG. 11 is an explanatory view of a further example of the method for forming the mask according to the present disclosure.

It should be understood that the drawings are not necessarily to scale and that the embodiments are sometimes illustrated by graphic symbols, phantom lines, diagrammatic representations and fragmentary views. In certain instances, details which are not necessary for an understanding of the present invention or which render other details difficult to perceive may have been omitted. It should be understood, of course, that the invention is not necessarily limited to the particular embodiments illustrated herein. Like numbers utilized throughout the various Figures designate like or similar parts or structure.

### DETAILED DESCRIPTION OF THE INVENTION

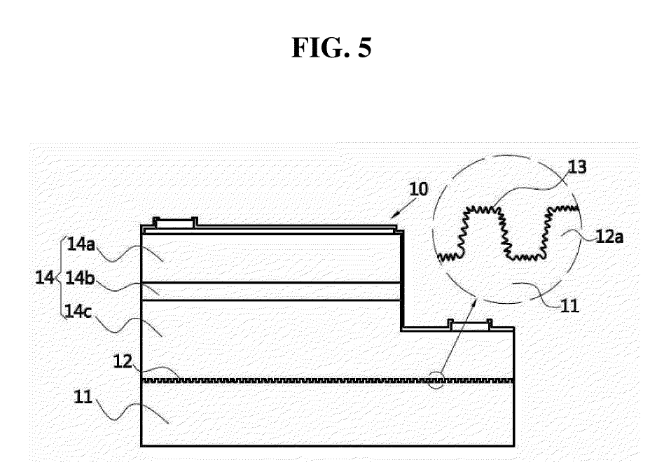

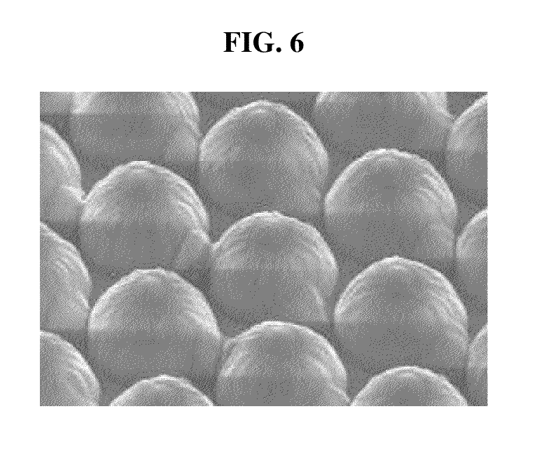

FIG. 5 illustrates one embodiment of a III-nitride semiconductor light emitting device according to the present disclosure, and FIG. 6 is a photograph of an example of a substrate with a scattering surface and a sub-scattering portion thereon according to the present disclosure. The III-nitride semiconductor light emitting device 10 (hereinafter, referred to as ‘light emitting device’) includes a substrate 11 (e.g., a sapphire substrate), III-nitride semiconductor layers 14 (hereinafter, referred to as ‘semiconductor layers’), a scattering surface 12 formed on the substrate 11, and a sub-scattering portion 13 formed on the scattering surface 12.

The semiconductor layers 14 are a plurality of semiconductor layers 14a, 14b and 14c grown on the substrate 11 and including an active layer 14b generating light by recombination of electrons and holes.

Here, a buffer layer may be further provided between the semiconductor layers 14 and the substrate 11.

Scattering surface 12 is provided to scatter light generated in the active layer 14b and incident on the substrate 11 to improve the external quantum efficiency of the light emitting device 10 and further to reduce crystal defects of the semiconductor layer 14 grown on the substrate 11. The scattering surface 12 includes at least a portion of rough or rugged surface formed on the substrate 11.

The scattering surface 12 may include sub-scattering portion 13 formed with a rough or rugged surface (bumps, small concave and convex portions and/or the like). The sub-scattering portion 13 can prevent the semiconductor layer 14 from being grown earlier on a part of the scattering surface 12 during the growth of the semiconductor layer 14.

Accordingly, it is possible to uniformly grow the semiconductor layer 14 over the scattering surface 12 and reduce crystal defects of the semiconductor layer 14.

In addition, the sub-scattering portion 13, which is formed on the scattering surface 12, is structurally smaller than the scattering surface 12. It is thus possible to more effectively scatter light and more improve the external quantum efficiency of the light emitting device 10.

The sub-scattering portion 13 may be provided as an irregular portion formed on the scattering surface 12.

The irregular portion is not limited to concave and convex parts which are regularly formed on the scattering surface 12 in a uniform shape, but includes parts formed in a non-uniform shape (e.g., a spherical shape, a corrugated shape, etc.) in terms of the shape or parts regularly or irregularly formed on the scattering surface 12 in terms of the location. Further, other types of rough surface can also be used in the present invention without departing from the spirit and scope of the invention.

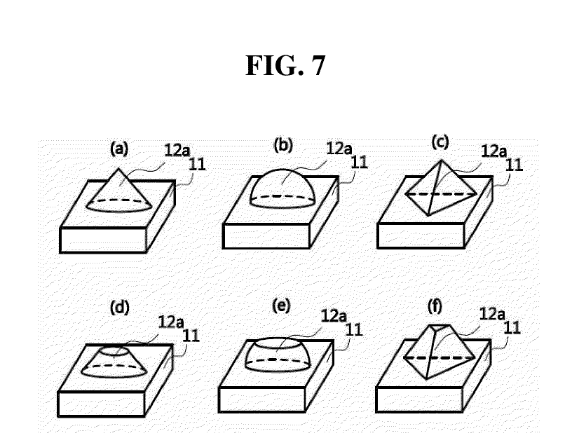

FIG. 7 illustrates examples of the scattering surface according to the present invention. The scattering surface 12 may include a convex portion 12a formed on the substrate 11. The convex portion 12a may be formed in any shape if it can scatter the light generated in the active layer 14b. Particularly, when a circumferential surface of the convex portion 12a is inclined to a bottom surface thereof, if an angle of the circumferential surface to the bottom surface is an acute angle, the convex portion 12a is advantageous in terms of the growth of the semiconductor layer 14.

That is, when the angle of the circumferential surface of the convex portion 12a to the bottom surface thereof is the acute angle, an angle of the circumferential surface of the convex portion 12a to the substrate 11 is an obtuse angle. Therefore, the semiconductor layer 14 can be effectively grown in the space between the adjacent convex portions 12a.

Moreover, the light generated in the active layer 14b can easily reach the circumferential surface of the convex portion 12a, which is preferable in terms of the scattering efficiency. Specifically, the convex portion 12a can be formed in the shape of a hemisphere, a circular cone and a polygonal cone in which the area is gradually reduced from the bottom surface to the apex and in the shape of a cylinder, an elliptic cylinder and a polygonal cylinder in which the area is gradually reduced from the bottom surface to the top surface.

The scattering surface 12 is not limited to the convex portion 12a formed on the substrate 11 in one shape, but includes convex portions formed in two or more shapes.

The convex portion 12a may be formed by a photolithography process and an etching process. Various shapes of convex portions 12a may be formed by changing the etching process conditions.

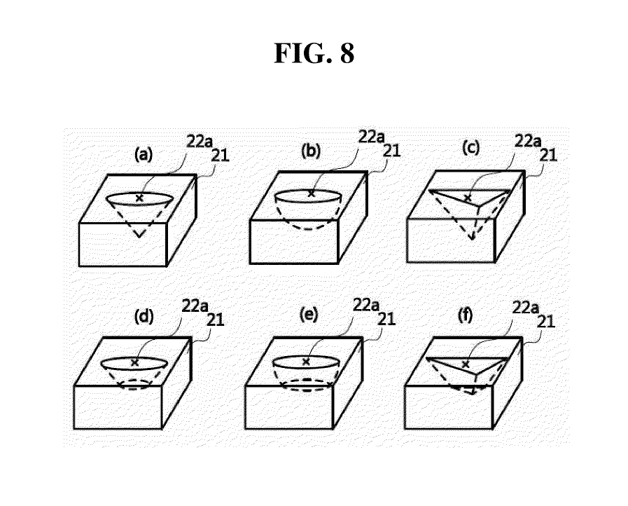

FIG. 8 illustrates other examples of the scattering surface according to the present invention. The scattering surface 12 may include concave portions 22a formed in the substrate 11. Like the convex portion 12a described above, the concave portion 22a may be formed in any shape if it can scatter the light generated in the active layer 14b. Particularly, when a circumferential surface of the concave portion 22a is inclined to a bottom surface of the concave portion 22a, if an angle of the bottom surface of the concave portion 22a to the circumferential surface thereof is an obtuse angle, the concave portion 22a is preferable in terms of the growth of the semiconductor layer 14 and the scattering efficiency.

Specifically, the concave portion 22a may be formed in the shape of a hemisphere, a circular cone, an elliptic cone and a polygonal cone in which the bottom is not a face but a point and the area is gradually reduced from the inlet to the bottom and in the shape of a cylinder, an elliptic cylinder and a polygonal cylinder in which the area is gradually reduced from the inlet to the bottom surface.

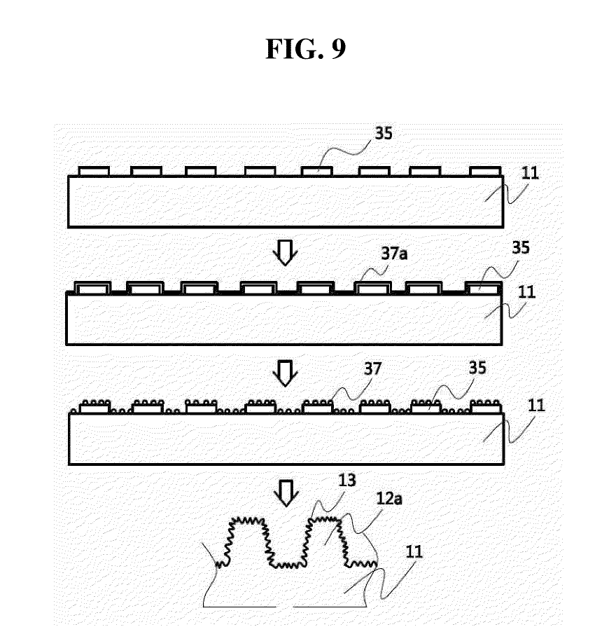

FIG. 9 is an explanatory view of an embodiment of a method for fabricating III-nitride semiconductor light emitting device according to the present invention, which includes a mask formation step and a dry etching step.

The mask formation step is to form a first mask 35 for forming a scattering surface 12 on a substrate 11 and a second mask 37 for forming a sub-scattering portion 13 on the scattering surface 12.

The first mask 35 may be formed by a photolithography process. That is, photoresist (PR) is coated on the substrate 11 and subjected to exposure and development, thereby forming the first mask 35.

The second mask 37 is formed by a step of forming a material layer 37a and a step of applying heat to the material layer 37a.

The material layer 37a may be formed on the substrate 11 with the first mask 35 thereon. The material layer 37a, which may be formed of a metal material such as Ag or Mg, is preferably coated at a thickness of 0.1 to 5 nm to effectively form the second mask 37.

The step of applying heat to the material layer 37a is provided to re-arrange material particles constituting the material layer 37a. When heat is applied to the material layer 37a, the material particles are re-arranged in a lump shape (e.g., a ball shape) to minimize the surface energy, thereby forming the second mask 37.

In addition to Ag and Mg mentioned above, any material containing material particles re-arranged by heat to have a resolution for forming the sub-scattering portion 13 may be used as the material for forming the second mask 37.

The dry etching step is provided to form the scattering surface 12 and the sub-scattering portion 13 by a dry etching process. The dry etching process may be any one of inductive coupled plasma etching, reactive ion etching, capacitive coupled plasma (CCP) etching, and electron-cyclotron resonance (ECR).

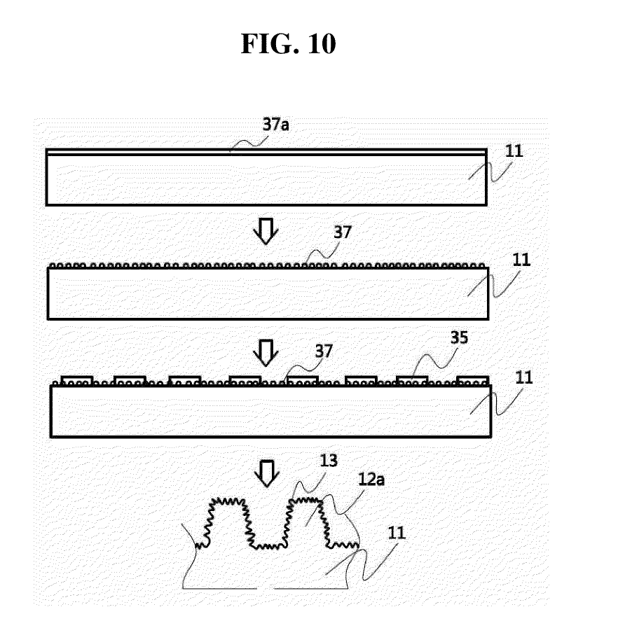

FIG. 10 is an explanatory view of another example of the method for forming the mask according to the present disclosure. A second mask 37 may be formed on a substrate 11, and then a first mask 35 may be formed thereon.

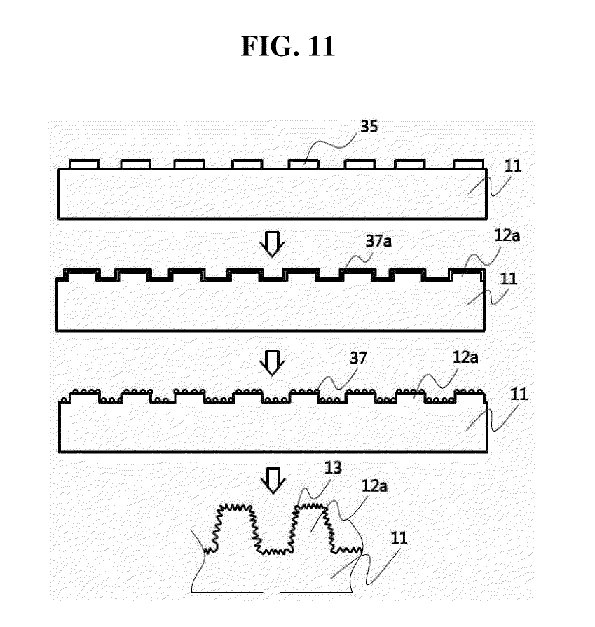

Moreover, FIG. 11 is an explanatory view of a further example of the method for forming the mask according to the present disclosure. A first mask 35 may be formed on a substrate 11, a scattering surface 12 may be formed by an etching process, and a second mask 37 may be formed on the scattering surface 12. Here, it is apparent that the etching process is not limited to dry etching but includes wet etching.

Hereinafter, various exemplary embodiments of the present disclosure will be described.

(1) A III-nitride semiconductor light emitting device, wherein a sub-scattering portion is provided as an irregular portion formed on a scattering surface.

(2) A III-nitride semiconductor light emitting device, wherein a sub-scattering portion is provided as a corrugated portion formed on a scattering surface.

The sub-scattering portion is intended to improve the scattering efficiency and prevent a semiconductor layer from being grown earlier on a part of a scattering surface to reduce crystal defects of the semiconductor layer.

(3) A III-nitride semiconductor light emitting device, wherein a scattering surface is formed by a convex portion provided on a substrate, and an angle of a circumferential surface of the convex portion to a bottom surface thereof is an acute angle.

(4) A III-nitride semiconductor light emitting device, wherein a scattering surface is formed by a concave portion provided in a substrate, and an angle of a circumferential surface of the concave portion to a bottom surface thereof is an obtuse angle.

Accordingly, a semiconductor layer can be effectively grown in the space between the adjacent convex portions or the space defined by the concave portion. In addition, the light generated in an active layer can easily reach the circumferential surface of the convex portion or the concave portion, which is preferable in terms of the scattering efficiency.

(5) A method for fabricating a III-nitride semiconductor light emitting device, wherein either a first mask for forming a scattering surface or a second mask for forming a sub-scattering portion is formed, and the other is formed thereon, wherein the second mask is formed by a step of forming a material layer and a step of applying heat to the material layer to re-arrange material particles constituting the material layer.

Therefore, a substrate having a scattering surface with a fine-size irregular portion thereon can be fabricated by the second mask having a greater resolution than that of the first mask. It is thus possible to improve the external quantum efficiency of the light emitting device and reduce crystal defects of the semiconductor layer.

According to the III-nitride semiconductor light emitting device of the present disclosure, since the light generated in the active layer is scattered by the sub-scattering portion as well as the scattering surface, there is an advantage in that the external quantum efficiency can be improved, and since the semiconductor layer is uniformly grown by the sub-scattering portion, there is an advantage in that crystal defects of the semiconductor layer can be reduced during the growth.

According to the method for fabricating the III-nitride semiconductor light emitting device of the present disclosure, the sub-scattering portion can be easily formed by the mask having a greater resolution than that of the mask formed by general photolithography. This improves the external quantum efficiency of the light emitting device and reduces crystal defects of the semiconductor layer.

Thus, there has been shown and described several embodiments of a novel invention. As is evident from the foregoing description, certain aspects of the present invention are not limited by the particular details of the examples illustrated herein, and it is therefore contemplated that other modifications and applications, or equivalents thereof, will occur to those skilled in the art.

The terminology used in the description of the invention herein is for the purpose of describing particular embodiments only and is not intended to be limiting of the invention. As used in the description of the embodiments of the invention and the appended claims, the singular forms “a”, “an” and “the” are intended to include the plural forms as well, unless the context clearly indicates otherwise.

Moreover, it will be understood that although the terms first, second and third are used herein to describe various features, elements, regions, layers and/or sections, these features, elements, regions, layers and/or sections should not be limited by these terms. These terms are only used to distinguish one feature, element, region, layer or section from another feature, element, region, layer or section. Thus, a first feature, element, region, layer or section discussed below could be termed a second feature, element, region, layer or section, and similarly, a second without departing from the teachings of the present invention.

The terms “having” and “including” and similar terms as used in the foregoing specification are used in the sense of “optional” or “may include” and not as “required”. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow. The scope of the disclosure is not intended to be limited to the embodiments shown herein, but is to be accorded the full scope consistent with the claims, wherein reference to an element in the singular is not intended to mean “one and only one” unless specifically so stated, but rather “one or more.” All structural and functional equivalents to the elements of the various embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A III-nitride semiconductor light emitting device comprising:
a substrate;
a plurality of III-nitride semiconductor layers grown over said substrate, said plurality of III-nitride semiconductor layers including an active layer for generating light by recombination of electrons and holes; and
a scattering surface formed on said substrate, said scattering surface scattering a light generated in said active layer, said scattering surface including at least a portion of rough or rugged surface formed on the substrate.

2. The III-nitride semiconductor light emitting device of claim 1, wherein said at least a portion of rough or rugged surface reduces crystal defects of said plurality of III-nitride semiconductor layers.

3. The III-nitride semiconductor light emitting device of claim 1, wherein said at least a portion of rough or rugged surface includes at least one irregular portion formed on said scattering surface.

4. The III-nitride semiconductor light emitting device of claim 1, wherein said at least a portion of rough or rugged surface includes at least one corrugated portion formed on said scattering surface.

5. The III-nitride semiconductor light emitting device of claim 1, wherein said scattering surface includes at least one convex portion formed on said substrate, and an angle of a circumferential surface of said at least one convex portion to a bottom surface of said at least one convex portion is an acute angle.

6. The III-nitride semiconductor light emitting device of claim 1, wherein the scattering surface includes at least one concave portion formed on said substrate, and an angle of a circumferential surface of said at least one concave portion to a bottom surface of said concave portion is an obtuse angle.

7. The III-nitride semiconductor light emitting device of claim 1, wherein the substrate is formed of sapphire, the scattering surface includes a convex portion, a concave portion or combination thereof formed on the substrate, said at least a portion of rough or rugged surface includes an irregular portion or a corrugated portion formed on the scattering surface, and said at least a portion of rough or rugged surface reduces crystal defects of said plurality of III-nitride semiconductor layers.

8. A method for fabricating a III-nitride semiconductor light emitting device as recited in claim 1, the method comprising:
a mask formation step of forming a first mask for forming a scattering surface on a substrate and a second mask for forming at least a portion of rough or rugged surface on the scattering surface; and
an etching step of forming said scattering surface and said at least a portion of rough or rugged surface by dry etching.

9. The method of claim 8, wherein the mask formation step is to form either the first mask or the second mask and form the other thereon.

10. The method of claim 8, wherein the mask formation step is to form the scattering surface by etching after the formation of the first mask and form the second mask on the scattering surface.

11. The method of claim 8, wherein the second mask is formed by a step of forming a preset material layer on the substrate and a step of applying heat to the material layer.

12. The method of claim 8, wherein either the first mask or the second mask is formed and the other is formed thereon,
wherein the second mask is formed by a step of forming a preset material layer on the substrate and a step of applying heat to the material layer.

13. A III-nitride semiconductor light emitting device comprising:
a substrate;
a plurality of III-nitride semiconductor layers grown over said substrate, said plurality of III-nitride semiconductor layers including an active layer for generating light by recombination of electrons and holes; and
a scattering surface formed on said substrate, said scattering surface scattering a light generated in said active layer, said scattering surface including a sub-scattering portion, said sub-scattering portion defining a rough or rugged surface formed on said scattering surface.

14. The III-nitride semiconductor light emitting device of claim 13, wherein said sub-scattering portion reduces crystal defects of the plurality of III-nitride semiconductor layers.

15. The III-nitride semiconductor light emitting device of claim 13, wherein said sub-scattering portion includes at least one irregular portion formed on said scattering surface.

16. The III-nitride semiconductor light emitting device of claim 13, wherein said sub-scattering portion includes at least one corrugated portion formed on said scattering surface.

17. The III-nitride semiconductor light emitting device of claim 13, wherein said scattering surface includes at least one convex portion formed on said substrate, and an angle of a circumferential surface of said at least one convex portion to a bottom surface of said at least one convex portion is an acute angle.

18. The III-nitride semiconductor light emitting device of claim 13, wherein the scattering surface includes at least one concave portion formed on said substrate, and an angle of a circumferential surface of said at least one concave portion to a bottom surface of said concave portion is an obtuse angle.

19. The III-nitride semiconductor light emitting device of claim 13, wherein the substrate is formed of sapphire, the scattering surface includes a convex portion, a concave portion or combination thereof formed on the substrate, said sub-scattering portion includes an irregular portion or a corrugated portion formed on the scattering surface, and said sub-scattering portion reduces crystal defects of said plurality of III-nitride semiconductor layers.
